(19) United States
(12) Patent Application Publication
(10) Pub. No.: US 2017/0285080 A1
(43) Pub. Date: Oct. 5, 2017

(54) POWER GRID SYSTEM AND METHOD OF DETERMINING POWER CONSUMPTION AT ONE OR MORE BUILDING CONNECTIONS IN A POWER GRID SYSTEM

(71) Applicant: SUN ELECTRIC PTE LTD, Singapore (SG)

(72) Inventor: Matthew PELOSO, Singapore (SG)

(21) Appl. No.: 15/507,286

(22) PCT Filed: Jun. 19, 2015
(86) PCT No.: PCT/SG2015/050170

§ 371 Date: Feb. 28, 2017

(30) Foreign Application Priority Data
Aug. 29, 2014 (SG) 10201405341Y

(51) Int. Cl. G01R 21/133

(52) U.S. Cl. CPC G01R 21/133

(57) ABSTRACT

Power grid system and method of determining power consumption at one or more building connections in a power grid system. The power grid system comprises a power grid comprising a mains grid portion; a plurality of building connections, each building connection comprising a first meter configured for metering power imported from the mains grid portion to the associated building and power exported from the associated building into the mains grid portion; for one or more of the building connections, at least one second meter disposed downstream from the first meter relative to the mains grid portion and configured for metering power exported to the associated building from an auxiliary generator; and a consolidation unit configured for determining power consumption at said one or more of the building connections based on readings from the associated first and second meters.

### FIELD OF INVENTION

The present invention relates broadly to a power grid system and to a method of determining power consumption thereof at one or more building connections in a power grid system.

### BACKGROUND

To date, the majority of buildings, in particular commercial buildings such as shopping malls or industrial buildings, obtain all their power from a mains power grid system. Any generation associated to the building is performed independently of the power network as an embedded generator to the building solely reducing the total energy drawn from the power network. This has left energy supply and associated issues such as technical development and integration of alternative or “green” energy sources etc., as well as systems and methods for financial settlement etc. under the responsibility of only a few entities, which may have hindered faster improvements in those areas.

On the other hand, owners or stakeholders in buildings which already have power being supplied from an auxiliary source such as photo-voltaic (PV) generators are facing technical issues associated with the independent connections to both a mains power grid and to a typically proprietary connection to the PV generators, including associated meters etc. This can result in increased complexity, including in terms of technical maintenance and calibration issues etc., the provision of necessary resources, both technical and administratively, for separate settlements, and liability issues.

Embodiments of the present invention provide a power grid system and a method of determining power consumption at one or more building connections in a power grid system that seek to address at least one of the above problems.

### SUMMARY

In accordance with a first aspect of the present invention, there is provided a power grid system comprising a power grid comprising a mains grid portion; a plurality of building connections, each building connection comprising a first meter configured for metering power imported from the mains grid portion to the associated building and power exported from the associated building into the mains grid portion; for one or more of the building connections, at least one second meter disposed downstream from the first meter relative to the mains grid portion and configured for metering power exported to the associated building from an auxiliary generator; and a consolidation unit configured for determining power consumption at said one or more of the building connections based on readings from the associated first and second meters.

In accordance with a second aspect of the present invention, there is provided a method of determining power consumption at one or more building connections in a power grid system, the method comprising metering power imported from a mains grid portion of the power grid system to a building associated with respective ones of the one or more building connections and power exported from the associated building into the mains grid portion using a first meter; metering, for one or more of the building connections, power exported to the associated building from an auxiliary generator using a second meter disposed downstream from the first meter relative to the mains grid portion; and determining power consumption at said one or more of the building connections based on readings from the first and from the second meters.

### BRIEF DESCRIPTION OF THE DRAWINGS

Embodiments of the present invention will be better understood and readily apparent to one of ordinary skill in the art from the following written description, by way of example only, and in conjunction with the drawings, in which:

FIG. 1 shows a schematic drawing illustrating a power grid system 100 according to an example embodiment.

FIG. 2 shows a flowchart illustrating a method of determining power consumption at one or more building connections in a power grid system and supply to a load at one or more building connections in a power grid system, according to an example embodiment.

FIG. 3 shows a series of voltages on a network associated with electrical conduction through various voltage transformers, each voltage level associated to a particular market settlement pool (.eg. Low Voltage, High Voltage, Extra High Voltage, etc.).

### DETAILED DESCRIPTION

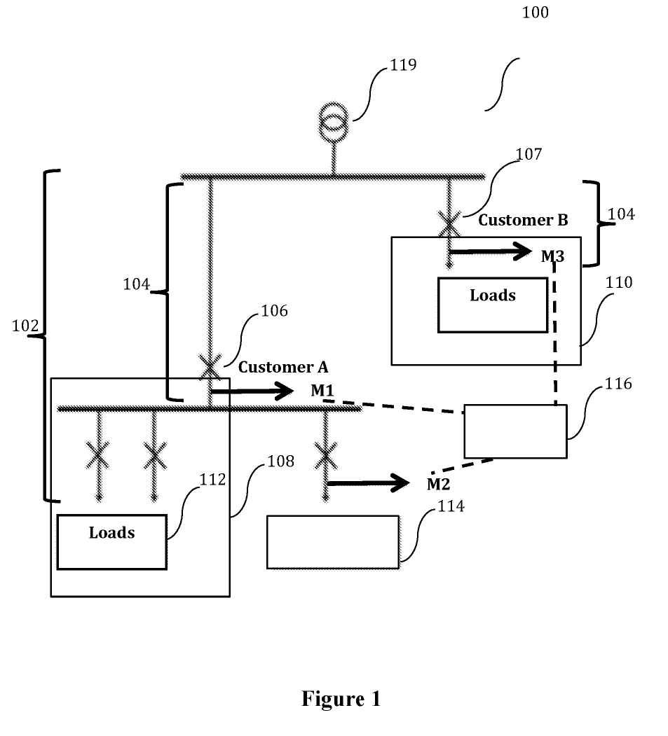

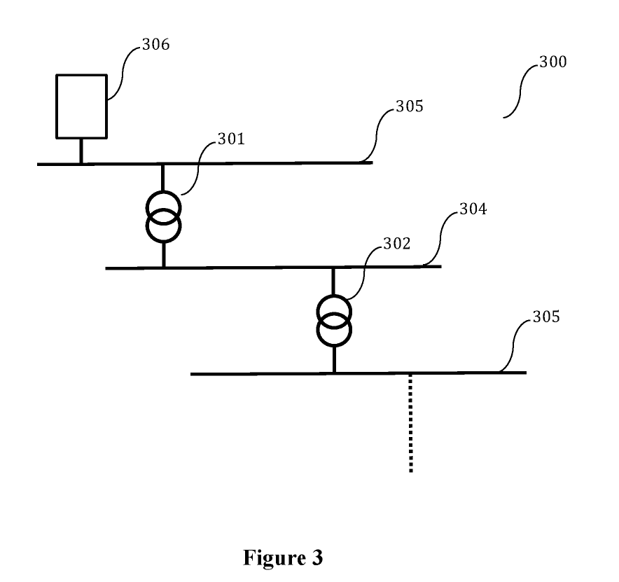

FIG. 1 shows a schematic drawing illustrating a power grid system 100 according to an example embodiment. The system 100 comprises a power grid 102 comprising a mains grid portion 104. The power grid 102 is associated through flow of electrons and holes through the network and is associated with various voltages defined through the placement of voltage transformers matching a corresponding specification. Typically, the mains supply for the power grid 102 is from a transformer 119, as a step down from a higher voltage level. The application of transformers for establishing the various voltages on the power grid 102 network is understood in the art and will not be described herein in any detail. FIG. 3 shows example voltage levels, e.g. Low Voltage 303, High Voltage 304, and Extra High Voltage 305 in a power grid network 300. Each of the transformers 301, 302 or the Extra High Voltage generator 306 can take the role of the transformer 119 illustrated in FIG. 1.

Returning to FIG. 1, the power grid 102 network is used to transfer power among loads from various sources of electricity. Conventionally this power grid 102 network is used to establish a central energy pool from which suppliers and consumers may trade, while the various voltages of the power grid 102 network may establish various markets and different settlements in pools associated to the specific voltage range.

The power grid system 100 further comprises a plurality of building connections e.g. 106, 107, each building connection e.g. 106, 107 comprising bi-directional meters e.g. M1, M3, configured for metering power imported from the mains grid portion 104 to the associated building e.g. 108, 110 and power exported from the associated building e.g. 108, 110 into the mains grid portion 104. For one or more of the building connections e.g. 106 a further meter M2 is disposed downstream from the first meter M1 relative to the mains grid portion 104 and is configured for metering power exported to one or more loads 112 in the associated building e.g. 108 from an auxiliary generator e.g. 114. In this example embodiment, the meter M2 is bi-directional, but it is noted that the meter M2 can be uni-directional in other embodiments, as will be appreciated by a person skilled in the art.

It is noted that more than one second meter may be provided downstream from one building connection. For example, each second meter may be associated with a different auxiliary generator at or near the same building.

A consolidation unit 116 of the system 100 is configured for determining power consumption at the one or more building connections e.g. 106 having the meter M2 based on readings from the meters M1 and M2.

The consolidation unit 116 may be specially constructed for the required purposes, or may comprise a general purpose computer or other device selectively activated or reconfigured by a computer program stored in the computer. The algorithms and outputs presented herein are not inherently related to any particular computer or other apparatus. Various general purpose machines may be used with programs in accordance with the teachings herein. Alternatively, the construction of more specialized apparatus to perform the required method steps may be appropriate. In addition, the present specification also implicitly discloses a computer program, in that it would be apparent to the person skilled in the art that the individual steps of the method described herein may be put into effect by computer code. The computer program is not intended to be limited to any particular programming language and implementation thereof. It will be appreciated that a variety of programming languages and coding thereof may be used to implement the teachings of the disclosure contained herein. Moreover, the computer program is not intended to be limited to any particular control flow. There are many other variants of the computer program, which can use different control flows without departing from the spirit or scope of the invention.

Furthermore, one or more of the steps of the computer program may be performed in parallel rather than sequentially. Such a computer program may be stored on any computer readable medium. The computer readable medium may include storage devices such as magnetic or optical disks, memory chips, or other storage devices suitable for interfacing with device selectively activated or reconfigured by the computer program. The computer readable medium may also include a hard-wired medium such as exemplified in the Internet system, or Wireless medium such as exemplified in the GSM mobile telephone system. The computer program when loaded and executed on the device effectively results in an apparatus that implements the steps of the preferred method.

The consolidation unit 116 may also be implemented as hardware modules. More particularily, in the hardware sense, a module is a functional hardware unit designed for use with other components or modules. For example, a module may be implemented using discrete electronic components, or it can form a portion of an entire electronic circuit such as an Application Specific Integrated Circuit (ASIC). Numerous other possibilities exist. Those skilled in the art will appreciate that the system can also be implemented as a combination of hardware and software modules.

The consolidation unit 116 in the example embodiment is configured for determining the power consumption at the building connections 106 by calculating:

C=M₁ᵢₘₚₒᵣₜ−M₁ₚₒᵣₜ+M₂ₑₓₚₒᵣₜ (1),

where C is the consumed power, M₁ᵢₘₚₒᵣₜ is the power imported from the mains grid portion 104 to the associated building 108, M₁ₑₓₚₒᵣₜ is the power exported from the associated building 108 into the mains grid portion 104 and M₂ₑₓₚₒᵣₜ is the power exported to the associated building 108 from the auxiliary generator 114.

As will be appreciated by a person skilled in the art, a transmission loss through this hardware may be incorporated within equation (1) to more accurately compute the flow of energy through the consolidation unit 116 by subtraction of the absolute transmission loss or through other means. In this embodiment it is assumed that this transmission loss is negligible and it is not investigated further.

Also, it will be appreciated by a person skilled in the art that equation (1) can be readily extended to account for two or more second meters downstream of the associated building connection.

The consolidation unit 116 is further configured for determining power supplied by the auxiliary generator 114 to the power grid 102 on the basis of the reading from the meter M2. The consolidation unit 116 is further configured for settling an aggregate supply of power from a plurality of auxiliary generators to one or more loads connected on the power grid system 100.

In the following, example cases illustrating the determining of the power consumption in the consolidation unit 116 will be described, by way of example, not limitation.

The above system can be summarised by the following process flow, each step of which may be completed in a variety of combinations to obtain the same outcome.

```
Assign A = 0,A ∈ {0,1}.
Assign C⁰ as customer load {normal procedure}, G⁰ = 0 as generator
supply.
Condition {“M₁ [symbol]   M₂”}: Install M₁, a bi-directional meter, at the
incoming line; and install M₂, e.g. a unidirectional meter,
at the generator.
IF { M₁ [symbol]   M₂}; A = 1; else{ };
Assign C¹ as customer load {modified procedure}, G¹ as generator supply.
Compute
      C¹ = M₁ + M₂;
      G¹ = M₂;
End;
```

It will be appreciated by the person skilled in the art that in the above algorithm, the default system is established to reflect a conventional working power network wherein there is no associated generator at the building and thus the consolidation unit can be set to the null set. Additionally, it will be appreciated by the person skilled in the art that more than one sources can be identified by the inclusion of more consolidations units A=2, A=3, et cetera.

### Assumptions:

The auxiliary generator 114 produces 50 kW over a specified consolidation period and exports all of the power via the meter M2.

Case 1: The loads 112 in the associated building 108 consume 100 kW over the specified consolidation period.

For the specified consolidation period, M1 meters that no power was exported from the building 108 to the mains grid portion 104 and that 50 kW were imported from the mains grid portion 104 into the building 108, being the difference between the power provided by the auxiliary generator 114 and the power consumed by the loads 112.

M2 meters 50 kW being exported from the auxiliary generator 114 to the building 108 during the specified consolidation period.

Accordingly, based on equation (1) above, the calculated power consumption C at building connection 106 is:

C=50 kW−0 kW+50 kW=100 kW.

The power consumption determined by the consolidation unit 116 in the example embodiment can preferably be used for settlement in an energy pool associated with the power grid system 100. In the Case 1 scenario, the power client associated with the building 108 will have to settle a consumption bill for 100 kW in the pool, i.e. consistent with the actual consumption at the loads 112.

On the other hand, the owner or stakeholder of the auxiliary generator 114 is settled on the basis of having sold 50 kW into the pool.

Case 2: The loads 112 in the associated building 108 consume 25 kW over the specified consolidation period.

For the specified consolidation period, M1 meters that 25 kW were exported from the building 108 to the mains grid portion 104 and that no power was imported from the mains grid portion 104 into the building 108, because the power needs of the loads 112 were fully met, and exceeded, by the auxiliary generator 114.

M2 again meters 50 kW being exported from the auxiliary generator 114 to the building 108 during the specified consolidation period.

Accordingly, based on equation (1) above, the calculated power consumption C at building connection 106 is:

C=0 kW−25 kW+50 kW=25 kW.

The power consumption determined by the consolidation unit 116 in the example embodiment can preferably be used for settlement in the energy pool associated with the power grid system 100. In the Case 2 scenario, the power client associated with the building 108 will have to settle a consumption bill for 25 kW in the pool, i.e. consistent with the actual consumption at the loads 112

On the other hand, the owner or stakeholder of the auxiliary generator 114 is again settled on the basis of having sold 50 kW into the pool. As will be appreciated by a person skilled in the art, the excess power provided by the auxiliary generator 114 into the pool can thus in effect be sold to other consumers, such as the power client associated with the building 110.

Case 3: The loads 112 in the associated building 108 consume no power over the specified consolidation period.

For the specified consolidation period, M1 meters that 50 kW were exported from the building 108 to the mains grid portion 104 and that no power was imported from the mains grid portion 104 into the building 108, because with no consumption at the loads 112, all of the power from the auxiliary generator was exported into the mains grid portion 104.

M2 again meters 50 kW being exported from the auxiliary generator 114 to the building 108 during the specified consolidation period.

Accordingly, based on equation (1) above, the calculated power consumption C at building connection 106 is:

C=0 kW−50 kW+50 kW=0 kW.

The power consumption determined by the consolidation unit 116 in the example embodiment can preferably be used for settlement in the energy pool associated with the power grid system 100. In the Case 3 scenario, the power client associated with the building 108 will incur no power charge, i.e. consistent with the (zero) consumption at the loads 112.

On the other hand, the owner or stakeholder of the auxiliary generator 114 is again settled on the basis of having sold 50 kW into the pool. As will be appreciated by a person skilled in the art, the excess power provided by the generator 114 into the pool can thus in effect be sold to other consumers, such as the power client associated with the building 110.

For example, Customer B and/or Customer C can be supplied based on a flexible settlement implementation in an example embodiment, as follows.

Case 4: Assuming a total aggregate generation of 50 kW or more at the sources as measured through one or more consolidation units, and a demand of 25 kW at Customer B, and 25 kW at Customer C.

25 kW of units are settled with Customer B, while 25 kW are settled with Customer C.

Case 5: Assuming a total aggregate generation of 50 kW or more at the sources as measured through one or more consolidation units, and a demand of 50 kW at Customer B, and 0 kW at Customer C.

The total aggregate generation is settled with Customer B, and no energy is settled with Customer C.

As can be seen from the examples described above, example embodiments of the present invention can have one or more of the following advantages and technical effects:

Backward compatibility for power connections and pool settlements for power clients associated with buildings which previously had no power being supplied from an auxiliary generator;

Backward compatibility for power connections for power clients associated with buildings which already had power being supplied from an auxiliary generator, with the advantage of avoiding or at least reducing technical issues associated with independent connections to both a mains power grid and to a typically proprietary connection to the PV generators, including associated meters etc., which can result in a reduced complexity, including in terms of technical maintenance and calibration issues etc., the provision of necessary resources, both technical and administratively, for separate settlements, and liability issues;

Enabling power supply and settlement directly between the auxiliary generator and the energy pool associated with the power grid system, optimisation of the use of resources; and

To flexibly define a source and load; and

To reduce the costs of installing the associated hardware for integration of a generator directly to a power grid network; and

Creating new commercial links between the power client associated with the building an and the owner or stakeholder of the auxiliary generator, e.g. roof top rental, share in profits made from selling power into the pool associated with the power grid system, etc.

The auxiliary generator 114 may comprise a photo-voltaic (PV) generator. The PV generator may be disposed on a roof top area of the building 108.

The consolidation unit 116 may further be configured to determine power consumption at one or more other building connections e.g. 107 on the basis of the reading from the meter M3. The consolidation unit 116 may be configured for remotely reading any one or more of the meters M1-M3.

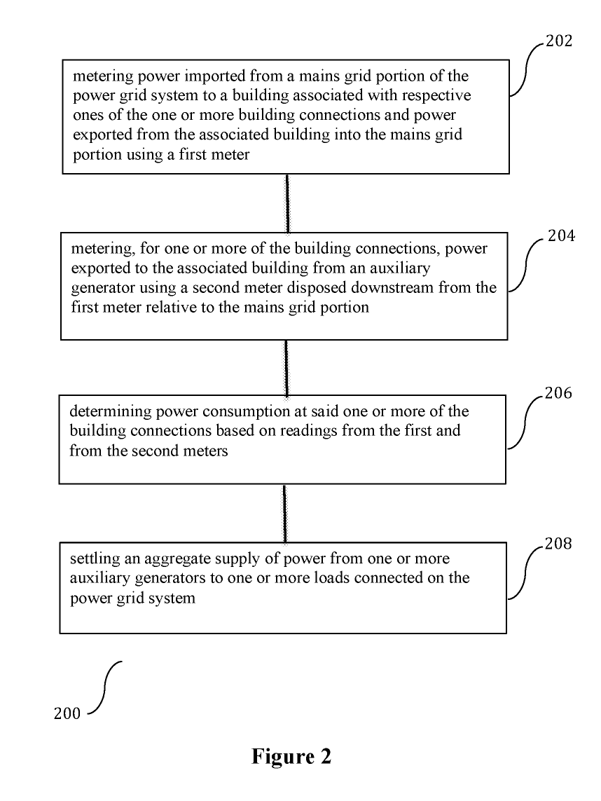

FIG. 2 shows a flowchart 200 illustrating a method of determining power consumption of one or more building connections in a power grid system, according to an example embodiment, and preferably allowing for the consolidated power units in aggregate, or as a fraction of the total generation at a given time, to be established through a settlement to one or more loads. At step 202, power imported from a mains grid portion of the power grid system to a building associated with respective ones of the one or more building connections and power exported from the associated building into the mains grid portion using a first meter are metered. At step 204, power exported to the associated building from an auxiliary generator using a second meter disposed downstream from the first meter relative to the mains grid portion is metered for one or more of the building connections. At step 206, power consumption at said one or more of the building connections is determined based on readings from the first and from the second meters.

Optionally, the method further comprises at step 208 settling an aggregate supply of power from one or more auxiliary generators to one or more loads connected on the power grid system.

The determining the power consumption may be by calculating C=M₁ᵢₘₚₒᵣₜ−M₁ₑₓₚₒᵣₜ+M₂ₑₓₚₒᵣₜ, where C is the consumed power, M₁ᵢₘₚₒᵣₜ is the power imported from the mains power grid to the associated building, M₁ₑₓₚₒᵣₜ is the power exported from the associated building into the mains power grid and M₂ₑₓₚₒᵣₜ is the power exported to the associated building from the auxiliary generator.

The method may further comprise determining power supplied by the auxiliary generator to the power grid on the basis of the reading from the second meter.

The auxiliary generator may comprise a photo-voltaic (PV) generator. The PV generator may be disposed on a roof top area of the building.

The method may further comprise determining power consumption at one or more other building connections on the basis of the reading from the first meter.

The method may comprise remotely reading the any one or more of the first and second meters.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive. Also, the invention includes any combination of features, in particular any combination of features in the patent claims, even if the feature or combination of features is not explicitly specified in the patent claims or the present embodiments.

For example, while for most practical applications the mains supply for the power grid would be from a transformer, typically as a step down as described in the example embodiments, it will be appreciated that the present invention would also apply if the power grid is supplied directly from a mains power generator.

1. A power grid system comprising:
a power grid comprising a mains grid portion;
a plurality of building connections, each building connection comprising a first meter configured for metering power imported from the mains grid portion to the associated building and power exported from the associated building into the mains grid portion;
for one or more of the building connections, at least one second meter disposed downstream from the first meter relative to the mains grid portion and configured for metering power exported to the associated building from an auxiliary generator; and
a consolidation unit configured for determining power consumption at said one or more of the building connections based on readings from the associated first and second meters.

2. The power grid system as claimed in claim 1, wherein the consolidation unit is configured for determining the power consumption by calculating C=M₁ᵢₘₚₒᵣₜ−M₁ₑₓₚₒᵣₜ+M₂ₑₓₚₒᵣₜ, where C is the consumed power, M₁ᵢₘₚₒᵣₜ is the power imported from the mains power grid to the associated building, M₁ₑₓₚₒᵣₜ is the power exported from the associated building into the mains power grid and M₂ₑₓₚₒᵣₜ is the power exported to the associated building from the auxiliary generator.

3. The power grid system as claimed in claim 1, wherein the consolidation unit is further configured for determining power supplied by the auxiliary generator to the power grid on the basis of the reading from the second meter.

4. The power grid system as claimed in claim 3, wherein the consolidation unit is further configured for settling an aggregate supply of power from one or more auxiliary generators to one or more loads connected on the power grid system.

5. The power grid system as claimed in claim 1, wherein the auxiliary generator comprises a photo-voltaic (PV) generator.

6. The power grid system as claimed in claim 5, wherein the PV generator is disposed on a roof top area of the building.

7. The power grid system as claimed in claim 1, wherein the consolidation unit is further configured to determine power consumption at one or more other building connections on the basis of the reading from the first meter.

8. The power grid system as claimed in claim 1, wherein the consolidation unit is configured for remotely reading any one or more of the first and second meters.

9. A method of determining power consumption at one or more building connections in a power grid system, the method comprising:
metering power imported from a mains grid portion of the power grid system to a building associated with respective ones of the one or more building connections and power exported from the associated building into the mains grid portion using a first meter;
metering, for one or more of the building connections, power exported to the associated building from an auxiliary generator using a second meter disposed downstream from the first meter relative to the mains grid portion; and
determining power consumption at said one or more of the building connections based on readings from the first and from the second meters.

10. The method as claimed in claim 9, wherein the determining the power consumption is by calculating C=M₁ᵢₘₚₒᵣₜ−M₁ₑₓₚₒᵣₜ+M_{2export,} where C is the consumed power, M₁ᵢₘₚₒᵣₜ is the power imported from the mains power grid to the associated building, M₁ₑₓₚₒᵣₜ is the power exported from the associated building into the mains power grid and M₂ₑₓₚₒᵣₜ is the power exported to the associated building from the auxiliary generator.

11. The method as claimed in claim 9, further comprising determining power supplied by the auxiliary generator to the power grid on the basis of the reading from the second meter.

12. The method as claimed in claim 10, further comprising settling an aggregate supply of power from one or more auxiliary generators to one or more loads connected on the power grid system.

13. The method as claimed in claim 9, wherein the auxiliary generator comprises a photo-voltaic (PV) generator.

14. The method as claimed in claim 13, wherein the PV generator is disposed on a roof top area of the building.

15. The method as claimed in claim 9, further comprising determining power consumption at one or more other building connections on the basis of the reading from the first meter.

16. The method as claimed in claim 1, comprising remotely reading the any one or more of the first and second meters.
